(19) United States
(12) Patent Application Publication
(10) Pub. No.: US 2026/0305329 A1
(43) Pub. Date: Oct. 1, 2026

(54) BACKSIDE POWER DELIVERY NETWORK WITH REDUCED RESISTANCE CONNECTION

(71) Applicant: International Business Machines Corporation, Armonk, NY (US)

(72) Inventors: Jidong Huang, Rexford, NY (US); Oscar van der Straten, Guilderland Center, NY (US); Xiaoming Yang, Clifton Park, NY (US); Tao Li, Slingerlands, NY (US); Liqiao Qin, Albany, NY (US); Ruilong Xie, Niskayuna, NY (US); Ravikumar Ramachandran, Pleasantville, NY (US)

(21) Appl. No.: 19/094,872

(22) Filed: Mar. 29, 2025

(51) Int. Cl. H01L 23/522; H01L 23/528; H01L 23/532; H10D 30/00; H10D 30/01; H10D 30/43; H10D 62/10; H10D 62/13; H10D 64/23; H10D 84/01; H10D 84/83

(52) U.S. Cl. CPC H10W 20/498; H10W 20/42; H10W 20/425; H10W 20/435; H10W 20/48; H10D 30/014; H10D 30/019; H10D 30/43; H10D 30/502; H10D 62/121; H10D 62/151; H10D 64/256; H10D 84/0149; H10D 84/8312; H10D 84/832; H10W 20/427; H10W 20/43

(57) ABSTRACT

A semiconductor structure includes a field effect transistor with a first drain-source region, a second drain-source region, at least one channel region connecting the first drain-source region and the second drain-source region, and a gate at least partially contacting the at least one channel region. A backside power delivery network is below the field effect transistor; a backside contact is connected to the backside power delivery network; a backside via is coupled directly to the backside contact and runs vertically upward next to the field effect transistor; and a frontside contact includes a frontside contact conductive fill coupled directly to the backside via and a frontside contact liner between the frontside contact conductive fill and one of the first drain-source region and the second drain-source region.

### BACKGROUND

The present invention relates generally to the electrical, electronic and computer arts and, more particularly, to backside power delivery networks (BSPDNs) for semiconductor devices and the like.

BSPDN schemes provide a connection for power delivery from the back side to the front side of a semiconductor device. Therefore, contact resistance in the connection is a pertinent factor that affects power delivery efficiency and device performance.

### BRIEF SUMMARY

Principles of the invention provide techniques for a backside power delivery network with a reduced resistance connection. In one aspect, an exemplary semiconductor structure includes a field effect transistor including a first drain-source region, a second drain-source region, at least one channel region connecting the first drain-source region and the second drain-source region, and a gate at least partially contacting the at least one channel region; a backside power delivery network below the field effect transistor; a backside contact connected to the backside power delivery network; a backside via coupled directly to the backside contact and running vertically upward next to the field effect transistor; and a frontside contact including a frontside contact conductive fill coupled directly to the backside via and a frontside contact liner between the frontside contact conductive fill and one of the first drain-source region and the second drain-source region.

In another aspect, another exemplary semiconductor structure includes a field effect transistor including a first drain-source region, a second drain-source region, at least one channel region connecting the first drain-source region and the second drain-source region, and a gate at least partially contacting the at least one channel region; a backside power delivery network below the field effect transistor; a backside contact connected to the backside power delivery network; a backside via coupled directly to the backside contact and running vertically upward next to the field effect transistor; and a frontside contact including a frontside contact conductive fill and a frontside contact liner. The frontside contact liner is directly between: (i) the frontside contact conductive fill and one of the first drain-source region and the second drain-source region; and (ii) the frontside contact conductive fill and the backside via.

In still another aspect, an exemplary method of forming a semiconductor device includes providing an initial semiconductor structure comprising: a field effect transistor including a first drain-source region, a second drain-source region, at least one channel region connecting the first drain-source region and the second drain-source region, and a gate at least partially contacting the at least one channel region; a backside via running vertically upward next to the field effect transistor; and a frontside contact portion including a frontside contact conductive fill and a frontside contact liner, the frontside contact liner separating the frontside contact conductive fill from one of the first drain-source region and the second drain-source region and from the backside via. Further steps include partially recessing the frontside contact portion to create a cavity; filling the cavity with additional conductive fill that directly contacts the frontside contact conductive fill and the backside via; forming a back-end-of-line layer in contact with the additional conductive fill; and forming a backside power delivery network in contact with the backside via.

As used herein, “facilitating” an action includes performing the action, making the action easier, helping to carry the action out, or causing the action to be performed. Thus, by way of example and not limitation, instructions executing on one processor might facilitate an action carried out by semiconductor fabrication equipment, by sending appropriate data or commands to cause or aid the action to be performed. Where an actor facilitates an action by other than performing the action, the action is nevertheless performed by some entity or combination of entities.

Techniques as disclosed herein can provide substantial beneficial technical effects. Some embodiments may not have these potential advantages and these potential advantages are not necessarily required of all embodiments. By way of example only and without limitation, one or more embodiments provide a BSPDN scheme that provides a low resistance connection for power delivery from a back side to a front side of a semiconductor device.

These and other features and advantages will become apparent from the following detailed description of illustrative embodiments thereof, which is to be read in connection with the accompanying drawings.

### BRIEF DESCRIPTION OF THE DRAWINGS

The following drawings are presented by way of example only and without limitation, wherein like reference numerals (when used) indicate corresponding elements throughout the several views, and wherein:

FIGS. 1, 2A, 2B, 3, 4A, 4B, 5, 6A, 6B, 7, 8A, 8B, 9A, 9B, 10, 11A, 11B, 12, 13A, 13B, 14, 15A, 15B, 16, 17A, and 17B show exemplary initial processing steps useful in connection with aspects of the invention;

FIGS. 18, 19A, 19B, 20A, 20B, 21A, 21B, 22A, and 22B show exemplary steps in an embodiment of the invention;

FIGS. 23A, 23B, 24A, and 24B show exemplary steps in another embodiment of the invention;

FIGS. 25A, 25B, 26A, 26B, 27A, 27B, 28A, 28B, 29A, and 29B show exemplary steps in another embodiment of the invention;

FIGS. 30A, 30B, 31A, 31B, 32A, 32B, 33A, 33B, 34A, 34B, 35A, 35B, 36A, and 36B show exemplary subsequent processing steps useful in connection with aspects of the invention;

FIGS. 37, 38A, and 38B show a “final” structure associated with the embodiment of FIGS. 18-22B, in accordance with an aspect of the invention;

FIGS. 39A and 39B show a “final” structure associated with the embodiment of FIGS. 23A-24B, in accordance with an aspect of the invention; and

FIGS. 40A and 40B show a “final” structure associated with the embodiment of FIGS. 25A-29B, in accordance with an aspect of the invention.

It is to be appreciated that elements in the figures are illustrated for simplicity and clarity. Common but well-understood elements that may be useful or necessary in a commercially feasible embodiment may not be shown in order to facilitate a less hindered view of the illustrated embodiments.

### DETAILED DESCRIPTION

Principles of inventions described herein will be in the context of illustrative embodiments. Moreover, it will become apparent to those skilled in the art given the teachings herein that numerous modifications can be made to the embodiments shown that are within the scope of the claims. That is, no limitations with respect to the embodiments shown and described herein are intended or should be inferred.

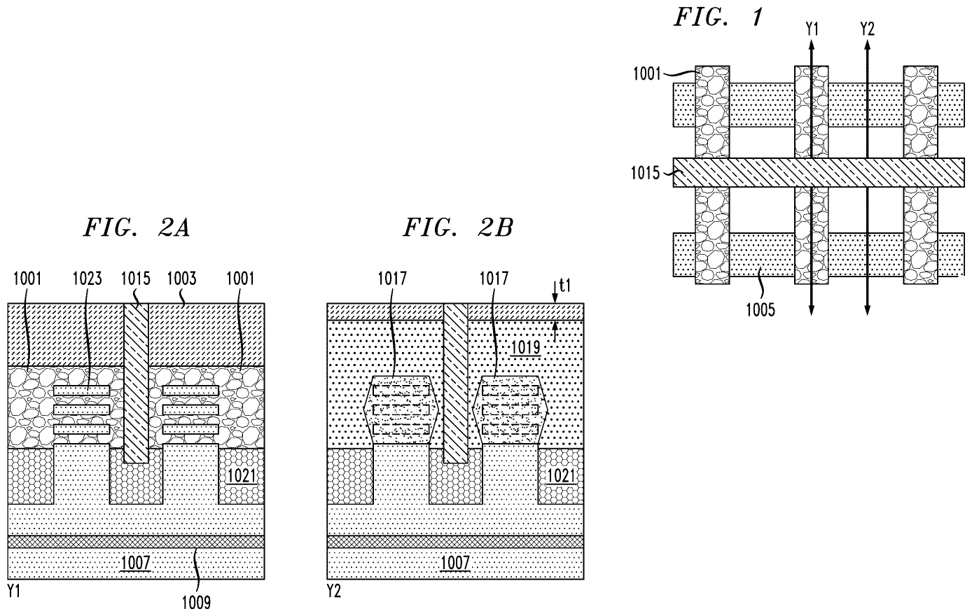

One or more embodiments include a BSPDN that provides a low resistance connection from a back side to a front side of a semiconductor device such as a circuit including field-effect transistors, for example. Initially, consider an exemplary process flow. Refer initially to the top view in FIG. 1 and the views along section lines Y1 and Y2 in FIG. 1 which are respectively presented in FIG. 2A (along line Y1) and FIG. 2B (along line Y2). Throughout, “A” figures are along line Y1 and “B” figures are along line Y2.

FIGS. 1, 2A, and 2B illustrate a starting structure, including gates 1001 (e.g., high-K metal gates), a metal gate capping layer 1003 (e.g., SiN), and regions 1005 where epitaxially grown source-drain regions are located, a substrate 1007, an etch stop layer (ESL) 1009, a gate cut 1015 (e.g., SiN), source-drain regions 1017, interlayer dielectric (ILD) 1019, and shallow trench isolation (STI) 1021. Note channel regions 1023 (e.g., nanosheets) including Si, for example. Chemical-mechanical planarization (CMP) can be used to form a layer with a thickness, for example, of 20 nm SiN (shown as t1). All dimensions herein are exemplary and non-limiting. The skilled artisan will be familiar with gate formation such as high-K metal gates (HKMG) formed using the replacement metal gate process, and with nanosheet stack formation including Si channels and sacrificial SiGe. Such gates include a high-K (e.g., hafnium-based) dielectric and metal portions such as, e.g., TiN, TiAlN, TiSiN, TaN, TaAlN, TaSiN, Tungsten (W), TiC, and the like.

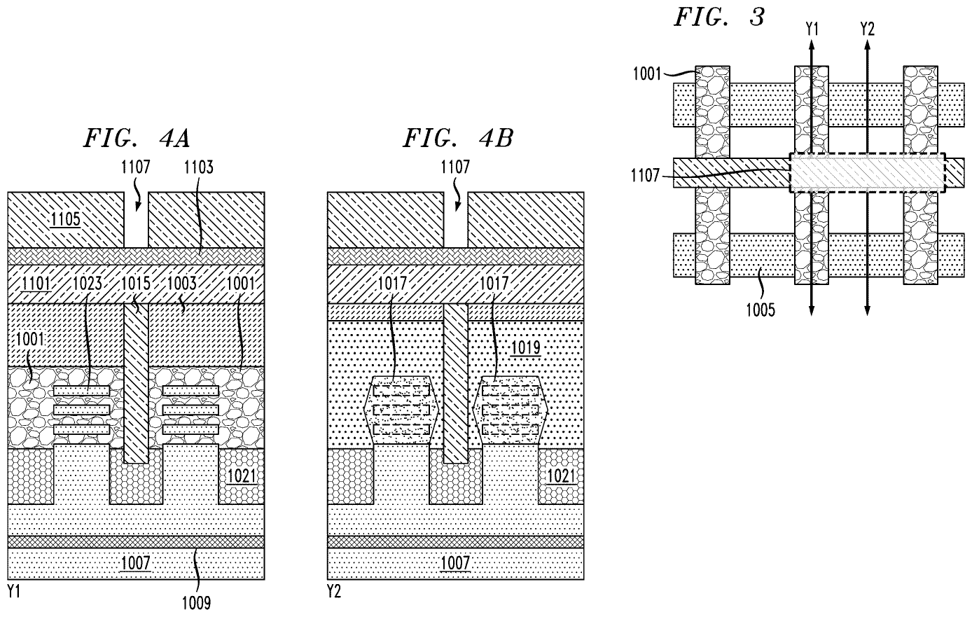

FIGS. 3, 4A, and 4B correspond to FIGS. 1-2B after lithography for via formation. Note organic planarization layer (OPL) 1101, silicon-containing antireflective coating (SiARC) 1103, photoresist 1105, and gap 1107 in the photoresist.

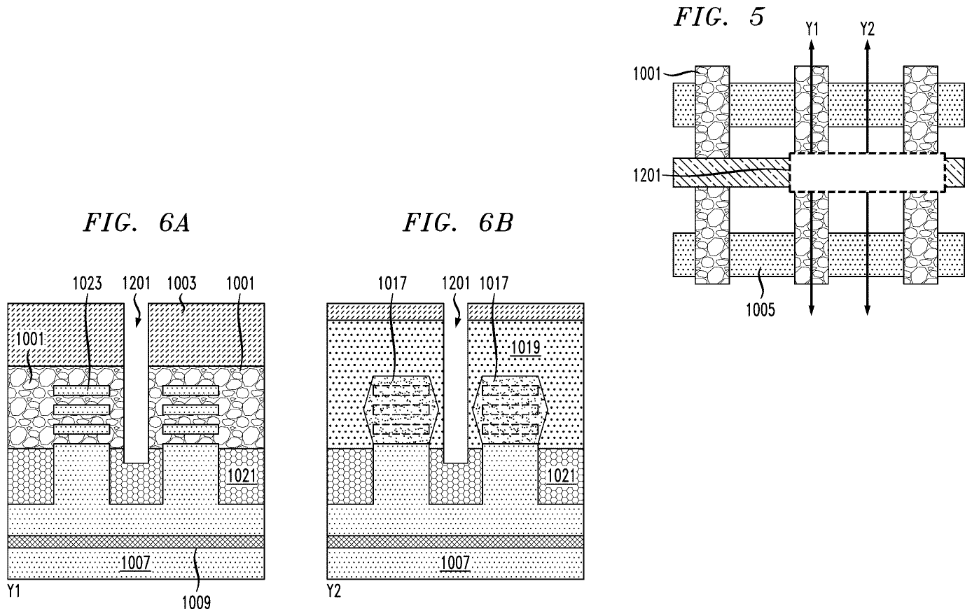

FIGS. 5, 6A, and 6B correspond to FIGS. 3-4B after via reactive ion etch (RIE)/ wet patterning. Note the via formation location 1201 etched (punched) from the front side down to the substrate, and the removal of the photoresist, SiARC, and OPL.

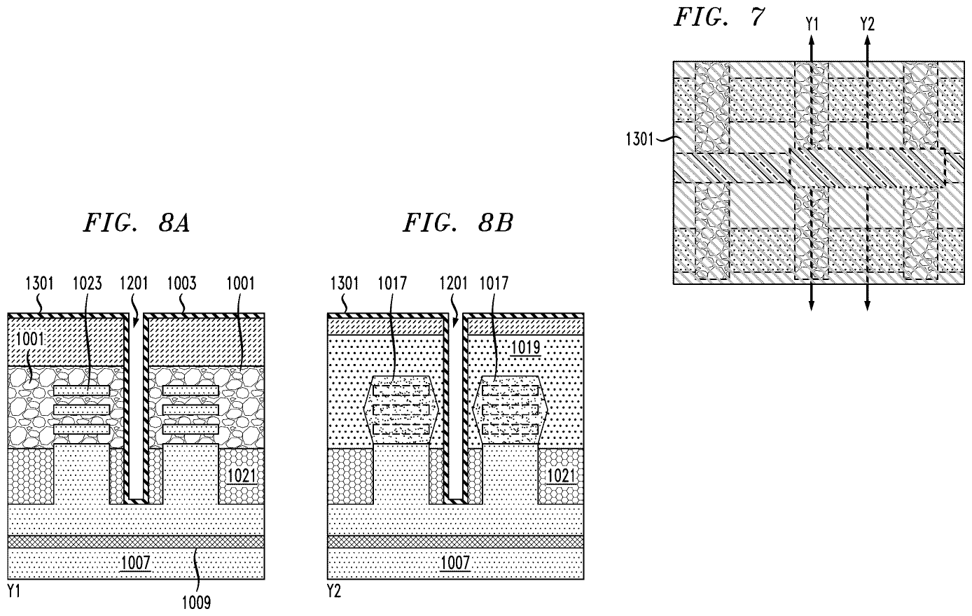

FIGS. 7, 8A, and 8B correspond to FIGS. 5-6B after SiN liner deposition to protect the via sidewalls. Note the SiN liner 1301 (other embodiments could use a different material; SiN is exemplary). The liner can include a thickness of, e.g., 7 nm. A critical dimension (CD) of the top of the via formation location 1201 can be, e.g., 16 nm.

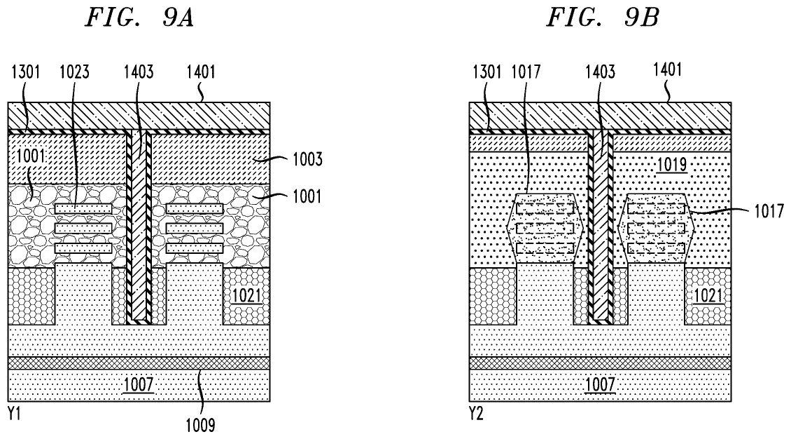

FIGS. 9A and 9B correspond to FIGS. 7-8B after deposition of tungsten (W) 1401 (or other suitable metal) for the via 1403 formed in via formation location 1201. The deposition can include a liner-less tungsten fill; i.e., filling tungsten into the via without the use of an additional non-tungsten liner besides SiN liner 1301. The fill can be formed by physical vapor deposition (PVD) of a tungsten liner with a thickness of, e.g., 6 nm plus chemical vapor deposition of the remaining tungsten for example. The remaining tungsten can be deposited to an adequate thickness to cover the structures where there is a need to fill (and can be followed by a polishing/CMP to remove the redundant amount above the structures). In a non-limiting example, 2000 Angstroms based on measurement on a blanket testing wafer can be used. Note that herein, when a top view such as FIG. 7 is generally indicative of the top view for a number of subsequent steps, a top view of each subsequent step is omitted for brevity.

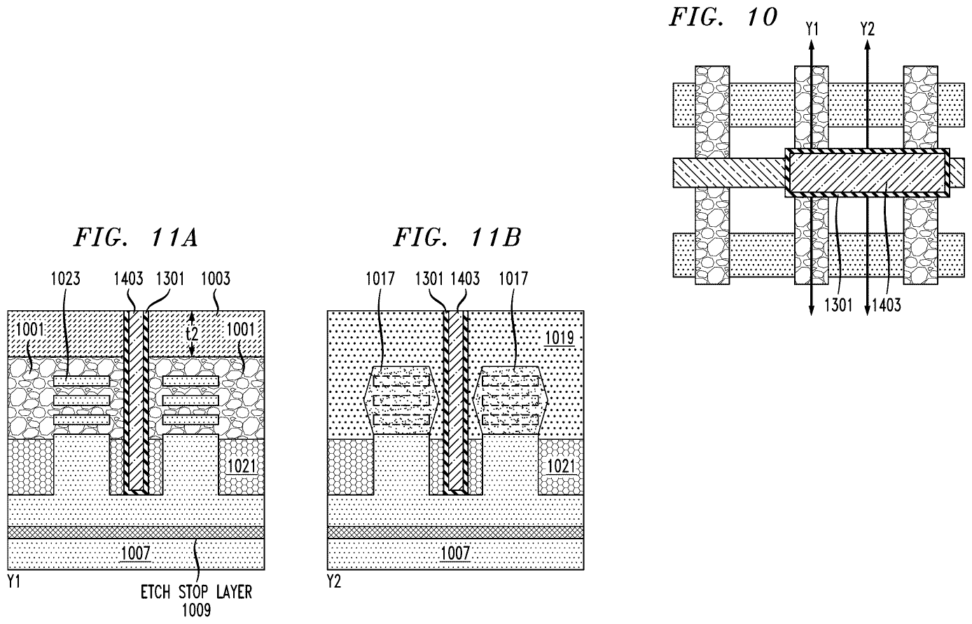

FIGS. 10, 11A, and 11B correspond to FIGS. 9A and 9B after planarization (e.g., CMP) of the structure of FIGS. 9A and 9B. Note the thickness (t2) of, e.g., 20 nm; materials in FIGS. 9A and 9B that were above the planarized surface depicted in FIGS. 11A and 11B have been removed in the planarization process.

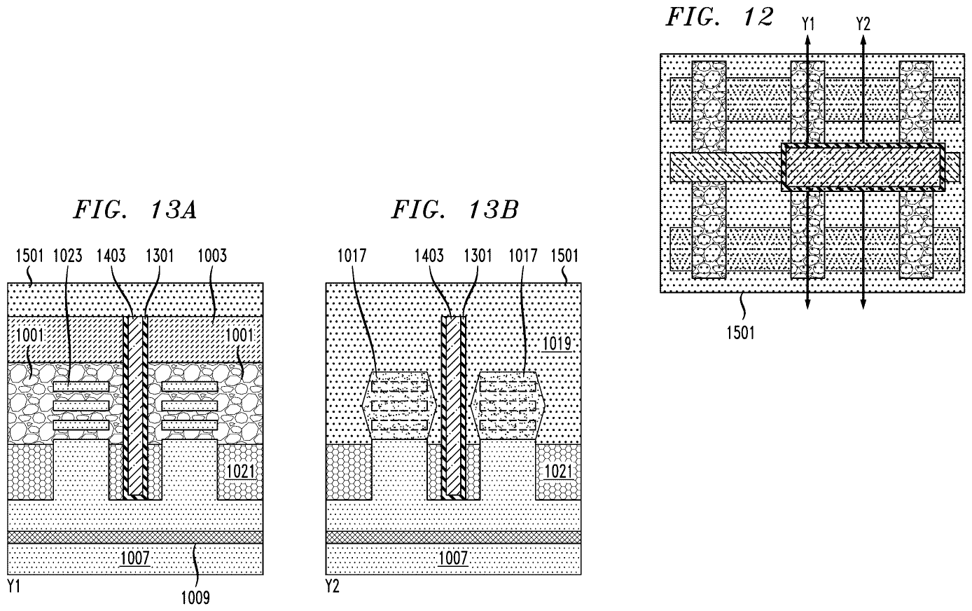

FIGS. 12, 13A, and 13B correspond to FIGS. 10-11B after deposition of additional interlayer dielectric (ILD) 1501 on outer surface of the structure depicted in FIGS. 11A and 11B, during the beginning of middle-of-line (MOL) processing.

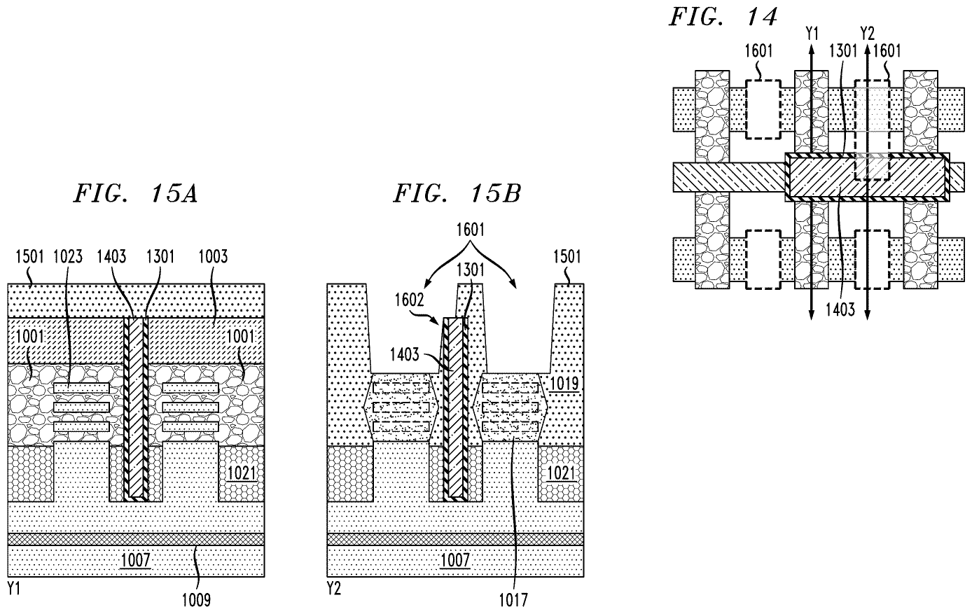

FIGS. 14, 15A, and 15B correspond to FIGS. 12-13B after lithography and patterning for reactive ion etching (RIE). Note the openings 1601 and the partial etch of the SiN liner 1301 of the via 1403 (as seen at 1602 in FIG. 15B) for an improved electrical connection. The openings 1601 will be used to form source-drain contacts.

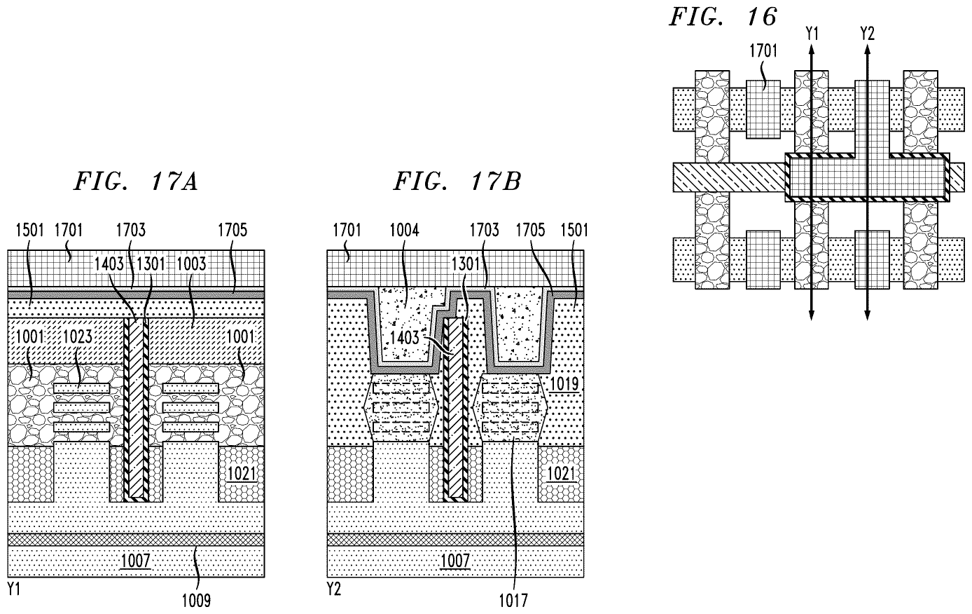

FIGS. 16, 17A, and 17B correspond to FIGS. 14-15B after deposition of a liner and tungsten to form the source-drain contacts. Note tungsten 1701 and a liner including TiN layer 1703 and Ti layer 1705. A thickness for the TiN layer 1703 can be, e.g., 30 Angstroms). A thickness for the Ti layer 1705 can be, e.g., 40 Angstroms. A thickness for the tungsten 1701 can be, e.g., an adequate thickness as discussed above.

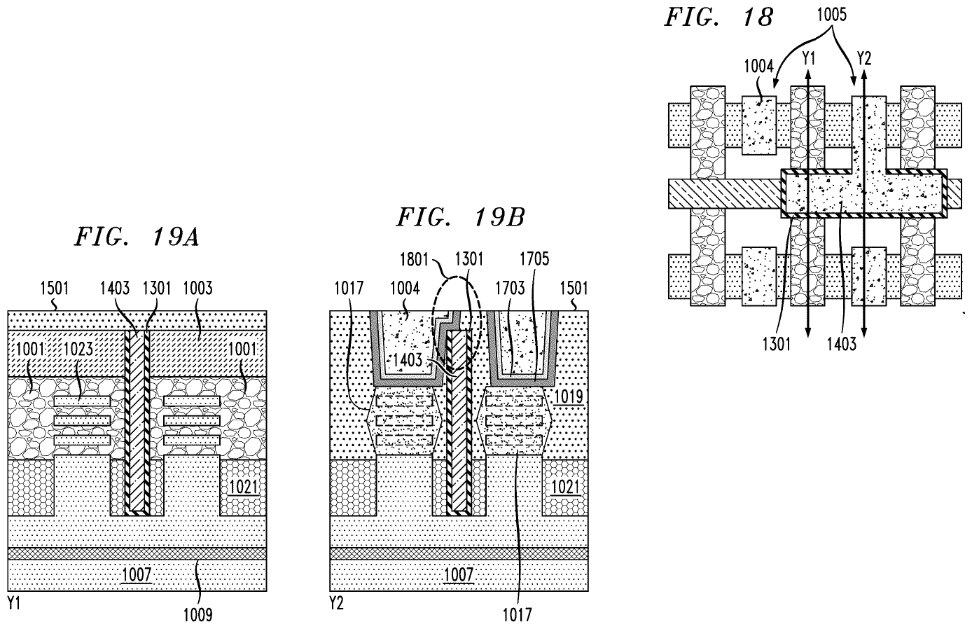

Considering now one embodiment of the invention, FIGS. 18, 19A, and 19B correspond to FIGS. 16-17B after planarizing (e.g., CMP) the structure in FIGS. 17A and 17B. Note in the dotted region 1801 the presence of the TiN layer 1703 and Ti layer 1705 which could result in undesirable resistance.

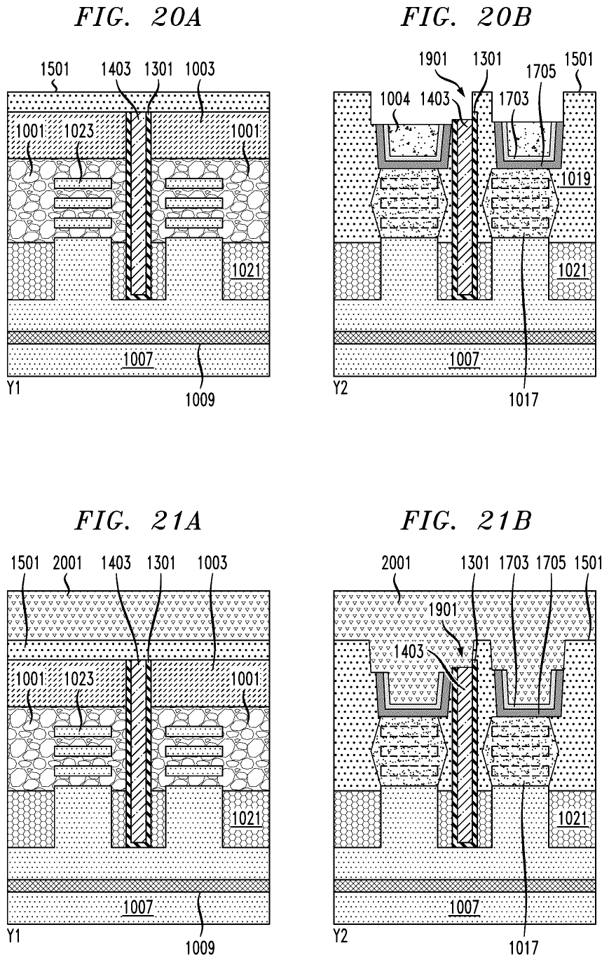

FIGS. 20A and 20B correspond to FIGS. 18-19B after recessing the tungsten 1701 and the liner including TiN layer 1703 and Ti layer 1705 at location 1901.

FIGS. 21A and 21B correspond to FIGS. 20A and 20B after linerless (i.e., no non-tungsten liner, thereby producing reduced resistance) deposition of additional tungsten 2001 (e.g., a tungsten-only liner deposited by PVD followed by remaining tungsten by chemical vapor deposition (CVD)). Note the desirable direct contact between the via 1403 and the source-drain contact at the location 1901.

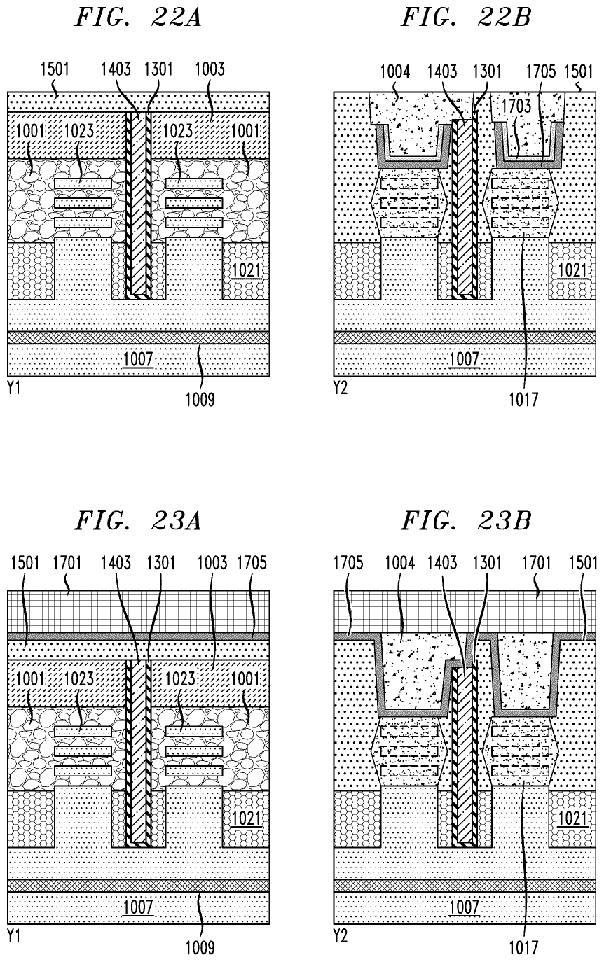

FIGS. 22A and 22B correspond to FIGS. 21A and 21B after planarization (e.g., CMP). Note the via 1403 and the SiN liner 1301. Note the desirable direct contact between the via 1403 and the source-drain contact 1004.

Considering now another embodiment of the invention, FIGS. 23A and 23B correspond to FIGS. 14-15B after deposition of a liner and tungsten to form the source-drain contacts. Note tungsten 1701 (e.g., 60 Angstroms PVD and an adequate thickness as discussed above by CVD) and a liner including Ti layer 1705 (e.g., 40 Angstroms). In this embodiment, note the absence of the high resistance TiN layer 1703 between the source-drain contact 1004 and the via 1403 as compared to FIGS. 17A and 17B.

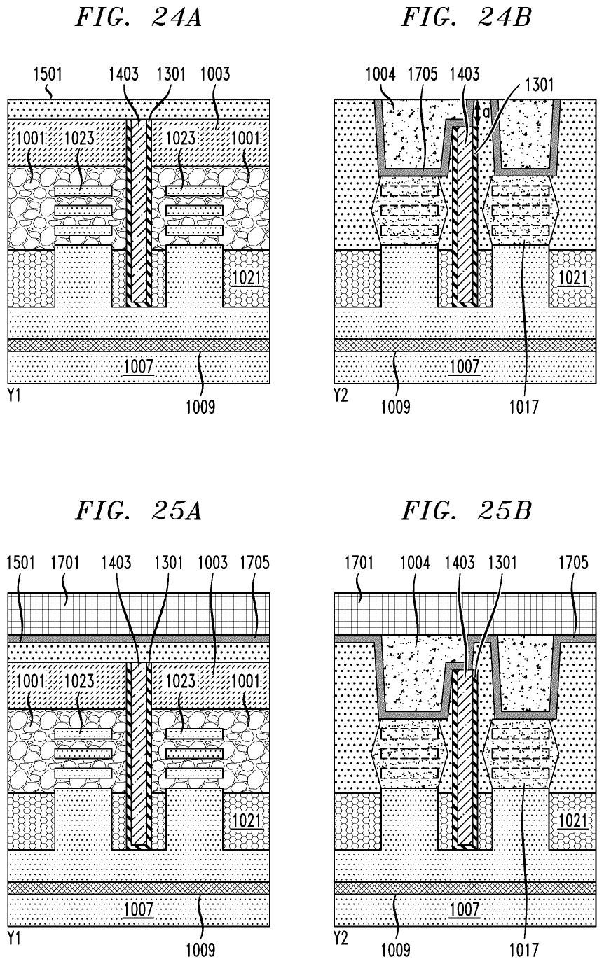

FIGS. 24A and 24B correspond to FIGS. 23A and 23B after planarization (e.g., CMP). Note the source-drain contact 1004 and the via 1403. A height difference (a) between the top of the contact and the top of the via can be, e.g., 20 nm.

Considering now still another embodiment of the invention, FIGS. 25A and 25B correspond to FIGS. 14-15B after deposition of a liner and tungsten to form the source-drain contacts. Note tungsten 1701 (e.g., 60 Angstroms PVD and an adequate thickness as discussed above by CVD) and a liner including Ti layer 1705 (e.g., 40 Angstroms). In this embodiment, note the absence of the high resistance TiN layer 1703 between the source-drain contact 1004 and the via 1403 as compared to FIGS. 17A and 17B.

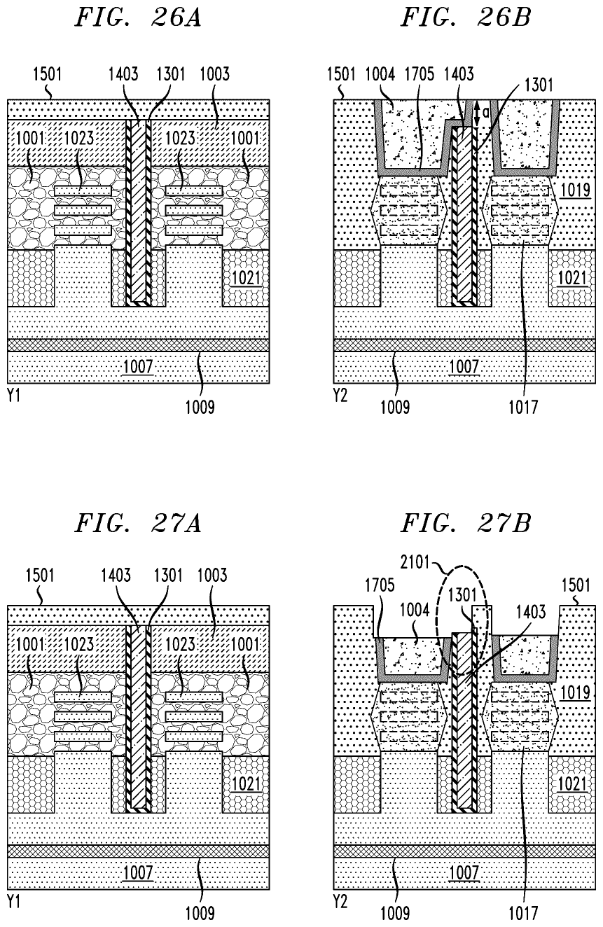

FIGS. 26A and 26B correspond to FIGS. 25A and 25B after planarization (e.g., CMP). Note the source-drain contact 1004 and the via 1403. A height difference (a) between the top of the contact and the top of the via can be, e.g., 20 nm.

FIGS. 27A and 27B correspond to FIGS. 26A and 26B after recessing the contact tungsten and the liner. Note removal of material at location 2101. Note source-drain contact 1004, the via 1403, the SiN liner 1301 and the Ti layer 1705.

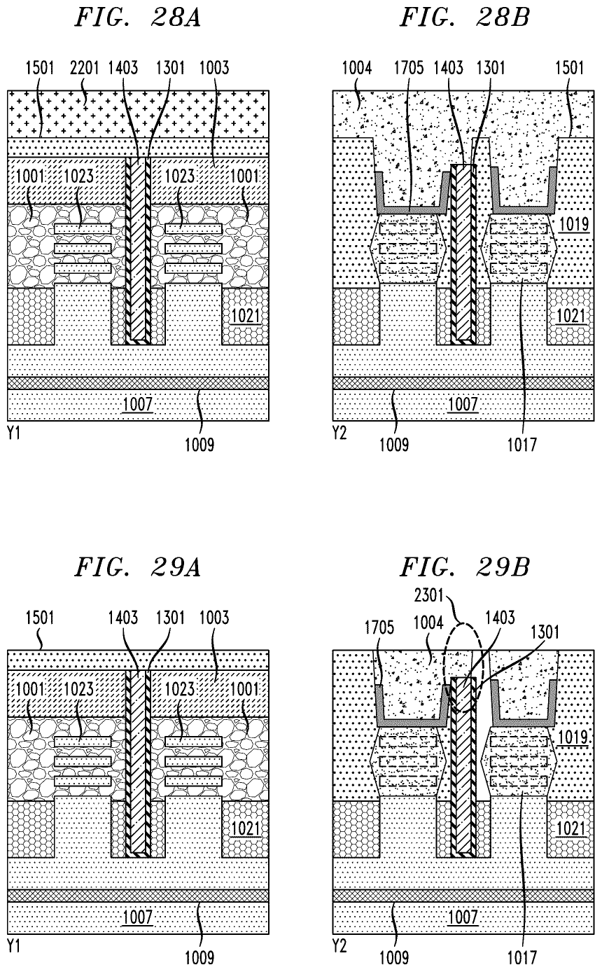

FIGS. 28A and 28B correspond to FIGS. 27A and 27B after linerless (i.e., no non-tungsten liner, thereby producing reduced resistance) deposition of additional tungsten 2201 (e.g., a tungsten liner deposited by PVD followed by remaining tungsten by CVD). Note the source-drain contact 1004.

FIGS. 29A and 29B correspond to FIGS. 28A and 28B after planarization (e.g., CMP). Note the source-drain contact 1004, the via 1403, SiN liner 1301, and the Ti layer 1705. Note the desirable direct contact between the via and the contact at location 2301.

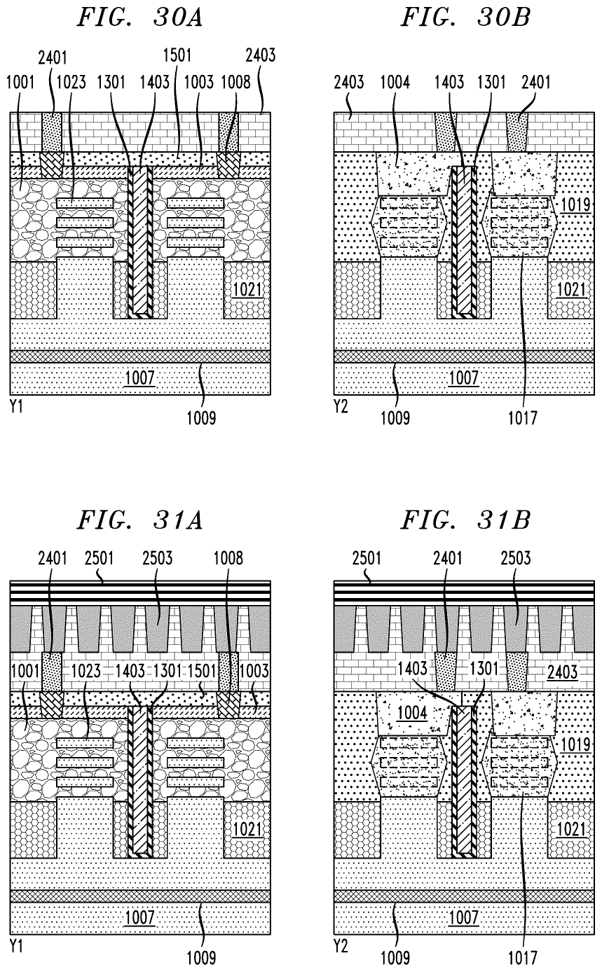

FIGS. 30A and 30B correspond with further processing any of the intermediate structures shown in FIGS. 22A and 22B, FIGS. 24A and 24B, or FIGS. 29A and 29B. Layers 1703 and/or 1705 are not shown for illustrative convenience in further processing but the operations depicted beginning with FIGS. 30A and 30B are applicable to all the embodiments. Additional ILD 2403 is deposited and patterned for gate contacts 1008 and vias 2401 which are metallized (e.g., 60 Angstroms PVD and an adequate thickness as discussed above by CVD). Note via 1403, SiN liner 1301, ILD 1019, and STI 1021.

FIGS. 31A and 31B correspond with FIGS. 30A and 30B, after formation of back end of line (BEOL) layers 2501 including connections to the vias 2401 via metal lines 2503.

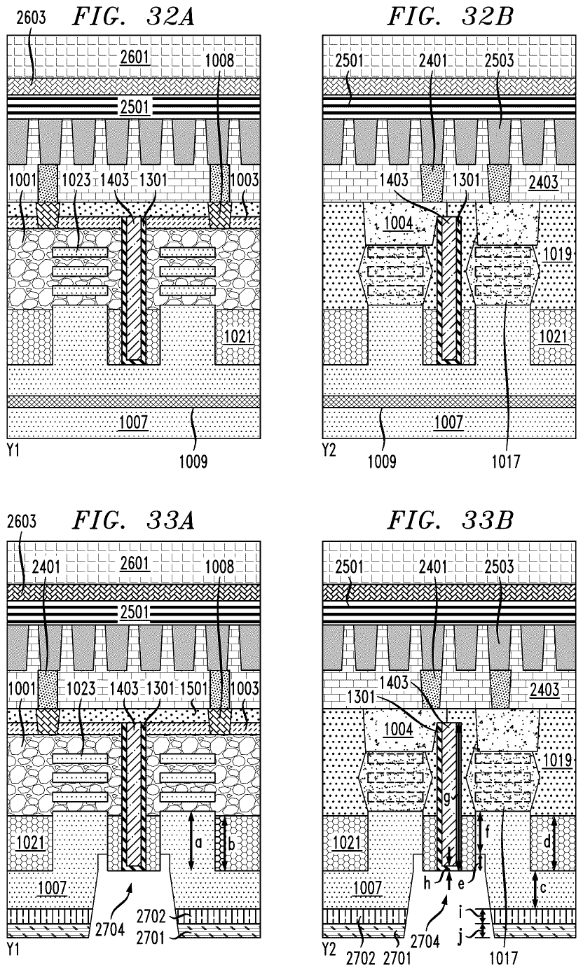

FIGS. 32A and 32B correspond with FIGS. 31A and 31B, after bonding a carrier wafer 2601 to the BEOL with bonding oxide 2603, and flipping the assembly over. Note that for illustrative convenience, the assembly is shown in its original orientation, not flipped. Between the configuration shown in FIGS. 32A and 32B and that shown in FIGS. 33A and 33B (discussed just below), carry out backside wafer grinding and CMP, wet removal of the substrate down to the etch stop layer 1009, and etch stop layer removal using a known wet process.

FIGS. 33A and 33B correspond with FIGS. 32A and 32B, after depositing backside ILD 2702 and patterning same with a hard mask 2701 (e.g., SiN) for backside via formation; note the cavities 2704 in which the backside contacts will be formed. Note various exemplary thicknesses: a=75 nm, b=60 nm, c=50 nm, d=60 nm, e=22 nm, f=55 nm, g=155.5 nm, h=7 nm, i=30 nm, and j=20 nm.

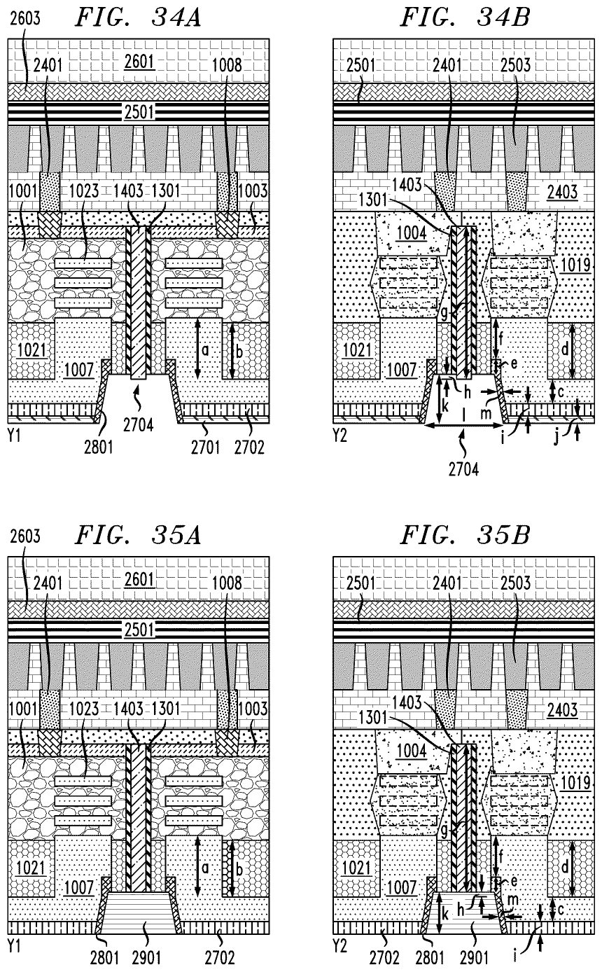

FIGS. 34A and 34B correspond with FIGS. 33A and 33B, after applying a liner 2801 (non-limiting examples include SiOx; SiCO; AlOx, and the like) to the cavity 2704 in which the backside contacts will be formed, and etching back the bottom of the SiN liner 1301 to expose the tungsten plug of the via 1403. Note various exemplary thicknesses: a=75 nm, b=60 nm, c=50 nm, d=60 nm, e=10 nm, f=55 nm, g=148.5 nm, h=5 nm, i=30 nm, j=3 nm, k=110 nm, l=42 nm, and m=5 nm.

FIGS. 35A and 35B correspond with FIGS. 34A and 34B, after deposition of tungsten to form the backside contacts 2901 (e.g., 60 Angstroms of tungsten by PVD and an adequate thickness as discussed above of tungsten by CVD), followed by planarization, such as CMP. Note that in the example there is a continuous path of tungsten material in the backside contact 2901, via 1403, source-drain contact 1004, and vias 2401, without low resistivity interfacial layer in between. Note various exemplary thicknesses: a=75 nm, b=60 nm, c=50 nm, d=60 nm, e=10 nm, f=55 nm, g=143.5 nm, h=12 nm, i=20 nm, and k=82 nm.

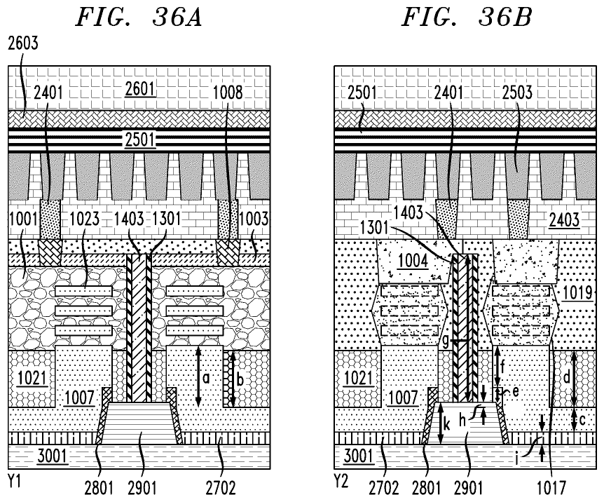

FIGS. 36A and 36B correspond with FIGS. 35A and 35B, after forming the rest of the BSPDN stack 3001 in a conventional manner. Note various exemplary thicknesses: a=75 nm, b=60 nm, c=50 nm, d=60 nm, e=10 nm, f=55 nm, g=143.5 nm, h=12 nm, i=20 nm, and k=82 nm.

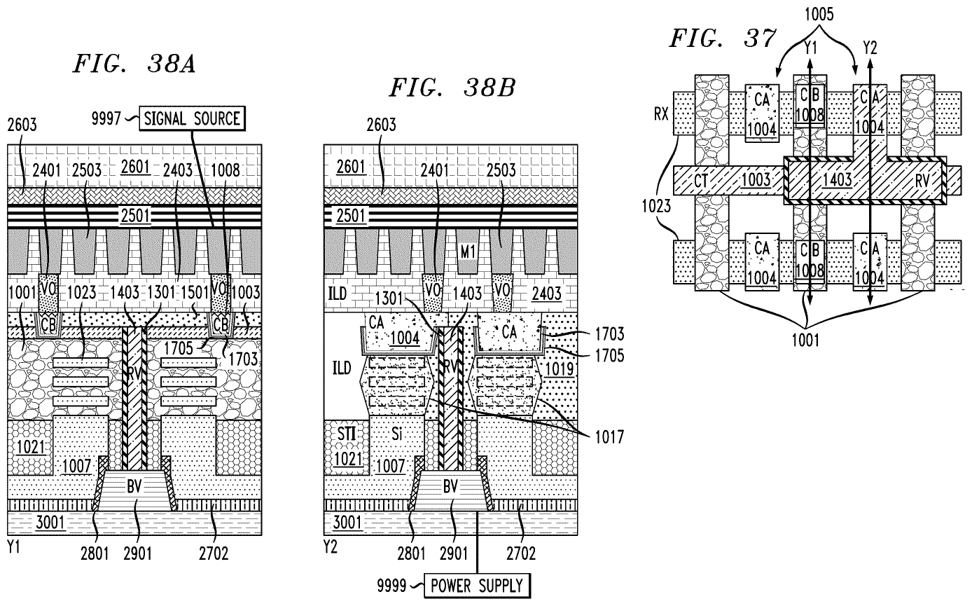

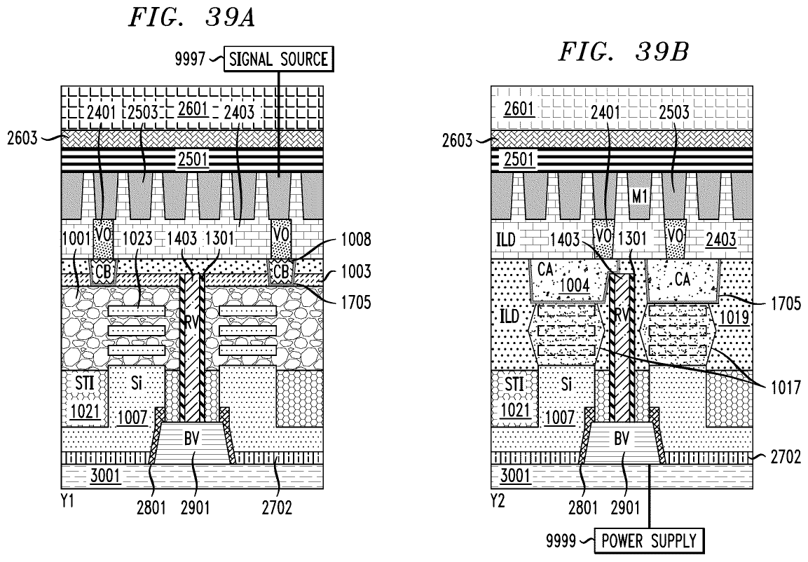

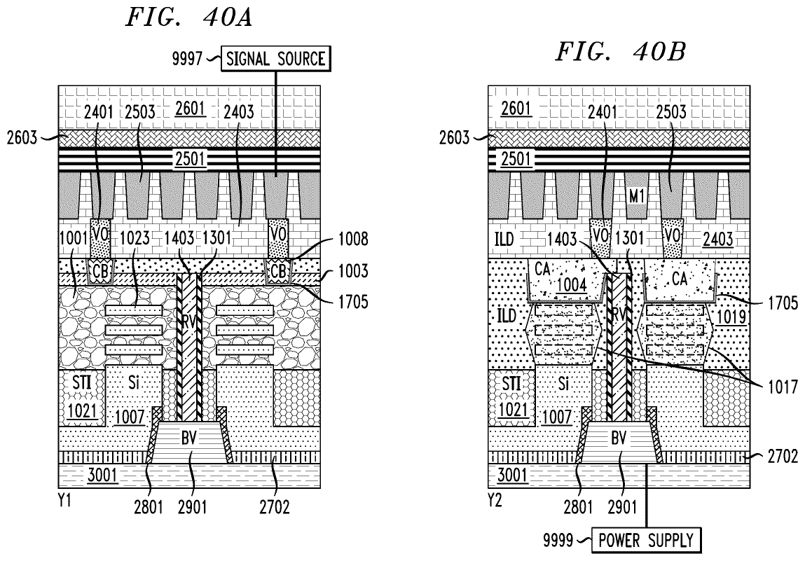

As noted. layers 1703 and 1705 were not shown for illustrative convenience in the further processing drawings. FIGS. 37, 38A, and 38B show the “final” version of the embodiment described beginning at FIGS. 18-19B; FIGS. 39A and 39B show the “final” version of the embodiment described beginning at FIGS. 23A and 23B; and FIGS. 40A and 40B show the “final” version of the embodiment described beginning at FIGS. 25A and 25B; “final” is placed in quotes because the skilled artisan will appreciate that the carrier wafer can be removed and further wiring and packaging steps can be typically carried out using known techniques.

Generally, a method of forming a semiconductor device includes patterning and metallization for elements, such as backside contacts 2901, vias 1403, frontside contacts (e.g., source-drain contacts 1004), and vias 2401, with linerless (as discussed above) PVD and CVD tungsten without a high resistance layer at their interface(s). One or more embodiments help to keep silicidation near source-drain contact 1004 unimpacted at the source/drain area.

A method includes providing a starting structure (see FIGS. 1-2B) including an etch stop layer, silicon substrate, using known techniques for fin, dummy gate, junction, replacement metal gate and gate cut processes. Further steps include lithography for the formation of the via 1403 and subsequent metallization; formation of the contacts (e.g., source-drain contacts 1004)/middle-of-line patterning; back-end-of-line (BEOL) processing; wafer flip; wafer backside substrate grinding; CMP; etch stop layer removal; backside power via patterning and metallization to form backside power vias (e.g., backside contacts 2901); and BSPDN metal stack formation.

Semiconductor device manufacturing includes various steps of device patterning processes. For example, the manufacturing of a semiconductor chip may start with, for example, a plurality of CAD (computer aided design) generated device patterns, which is then followed by effort to replicate these device patterns in a substrate. The replication process may involve the use of various exposing techniques and a variety of subtractive (etching) and/or additive (deposition) material processing procedures. For example, in a photolithographic process, a layer of photo-resist material may first be applied on top of a substrate, and then be exposed selectively according to a pre-determined device pattern or patterns. Portions of the photo-resist that are exposed to light or other ionizing radiation (e.g., ultraviolet, electron beams, X-rays, etc.) may experience some changes in their solubility to certain solutions. The photo-resist may then be developed in a developer solution, thereby removing the non-irradiated (in a negative resist) or irradiated (in a positive resist) portions of the resist layer, to create a photo-resist pattern or photo-mask. The photo-resist pattern or photo-mask may subsequently be copied or transferred to the substrate underneath the photo-resist pattern.

There are numerous techniques used by those skilled in the art to remove material at various stages of creating a semiconductor structure. As used herein, these processes are referred to generically as “etching”. For example, etching includes techniques of wet etching, dry etching, chemical oxide removal (COR) etching, and reactive ion etching (RIE), which are all known techniques to remove select material(s) when forming a semiconductor structure. The Standard Clean 1 (SC1) contains a strong base, typically ammonium hydroxide, and hydrogen peroxide. The SC2 contains a strong acid such as hydrochloric acid and hydrogen peroxide. The techniques and application of etching is well understood by those skilled in the art and, as such, a more detailed description of such processes is not presented herein.

Although the overall fabrication method and the structures formed thereby are novel, certain individual processing steps required to implement the method may utilize conventional semiconductor fabrication techniques and conventional semiconductor fabrication tooling. These techniques and tooling will already be familiar to one having ordinary skill in the relevant arts given the teachings herein. For example, the skilled artisan will be familiar with conventional techniques that can be adapted to form the starting structure, and with conventional techniques, such as lithography and etching, that can be adapted to carry out the patterning. The skilled artisan will be familiar with suitable materials for insulators (e.g., SiO₂), further metallization (e.g., copper with liners/barriers such as Ta, TaN), and the like.

Moreover, one or more of the processing steps and tooling used to fabricate semiconductor devices are also described in a number of readily available publications, including, for example: James D. Plummer et al., Silicon VLSI Technology: Fundamentals, Practice, and Modeling 1^{st} Edition, Prentice Hall, 2001 and P.H. Holloway et al., Handbook of Compound Semiconductors: Growth, Processing, Characterization, and Devices, Cambridge University Press, 2008. It is emphasized that while some individual processing steps are set forth herein, those steps are merely illustrative, and one skilled in the art may be familiar with several equally suitable alternatives that would be applicable.

It is to be appreciated that the various layers and/or regions shown in the accompanying figures may not be drawn to scale. Furthermore, one or more semiconductor layers of a type commonly used in such integrated circuit devices may not be explicitly shown in a given figure for ease of explanation. This does not imply that the semiconductor layer(s) not explicitly shown are omitted in the actual integrated circuit device.

Given the discussion thus far, it will be appreciated that, in general terms, referring to FIGS. 37-38B and 40A-40B, an exemplary semiconductor structure includes a field effect transistor including a first drain-source region (e.g., 1017 under a region 1005), a second drain-source region (e.g., 1017 under another region 1005), at least one channel region 1023 connecting the first drain-source region and the second drain-source region, and a gate 1001 at least partially contacting the at least one channel region. A backside power delivery network 3001 is below the field effect transistor. A backside contact 2901 is connected to the backside power delivery network. A backside via 1403 is coupled directly (i.e., no intervening material) to the backside contact and runs vertically upward next to the field effect transistor. A frontside contact (e.g., source-drain contact 1004) includes a frontside contact conductive fill coupled directly (i.e., no intervening material) to the backside via and a frontside contact liner (e.g., Ti layer 1705 or TiN layer 1703 with Ti layer 1705) between the frontside contact conductive fill and one of the first drain-source region and the second drain-source region.

Note that in one or more embodiments, there are multiple channel regions 1023 (nanosheets) and the gate 1001 is a replacement metal gate that surrounds the channels (gate all around).

In one or more embodiments, the semiconductor structure further includes a substrate 1007 under the field effect transistor and laterally spaced from the backside contact; a frontside via 2401 coupled directly (i.e., no intervening material) to the frontside contact conductive fill; and a back-end-of-line wiring layer 2501 coupled to the frontside via; where the backside via and the frontside contact are coupled laterally at an upper portion of the backside via (as seen at the top of the backside via 1403 in FIGS. 38B and 40B).

In some instances, the backside contact, the backside via, the frontside contact conductive fill, and the frontside via are all a same conductive material. For example, the same material can be selected from the group consisting of aluminum, ruthenium, tungsten, cobalt, and copper. In one specific example, the same material is tungsten.

In one or more embodiments, the backside via has sides, and the structure further includes a backside via liner (e.g., SiN liner 1301) on the sides of the backside via. The backside via liner can include, for example, silicon nitride.

Now referring specifically to FIGS. 37-38B, in some cases, the frontside contact liner includes: an inner layer 1705 adjacent the one of the first drain-source region and the second drain-source region; and an adhesion liner 1703 between the inner layer and the frontside contact conductive fill.

For example, the inner layer can be selected from the group consisting of nickel, nickel-platinum, and titanium; and the adhesion liner can be selected from the group consisting of titanium nitride and tantalum nitride.

In some specific instances, the inner layer is titanium; and the adhesion liner is titanium nitride.

Now referring specifically to FIGS. 40A and 40B, in some cases, the frontside contact liner is a single layer 1705 selected from the group consisting of nickel, nickel-platinum, and titanium. In some cases, the single layer is titanium. Any of the embodiments can further include a power supply 9999 coupled to the backside contact. For example, there can be a copper layer/line between the BSPDN and the backside contact. Any suitable integrated circuit power supply can be employed and can be connected using known techniques and can, for example, supply a fixed voltage. Any of the embodiments can further include a signal source 9997 (e.g., known integrated circuit signal source) coupled to the gate through the back-end-of-line wiring layer in a known manner.

In another aspect, referring to FIGS. 39A and 39B another semiconductor structure includes a field effect transistor including a first drain-source region (e.g., 1017 under a region 1005), a second drain-source region (e.g., 1017 under another region 1005), at least one channel region 1023 connecting the first drain-source region and the second drain-source region, and a gate 1001 at least partially contacting the at least one channel region. A backside power delivery network 3001 is below the field effect transistor. A backside contact 2901 is connected to the backside power delivery network. A backside via 1403 is coupled directly to the backside contact and runs vertically upward next to the field effect transistor. A frontside contact (e.g., source-drain contact 1004) includes a frontside contact conductive fill and a frontside contact liner 1705. The frontside contact liner is directly (i.e., no intervening material) between: (i) the frontside contact conductive fill and one of the first drain-source region and the second drain-source region; and (ii) the frontside contact conductive fill and the backside via.

One or more embodiments further include a substrate 1007 under the field effect transistor and laterally spaced from the backside contact; a frontside via 2401 coupled directly (i.e., no intervening material) to the frontside contact conductive fill; and a back-end-of-line wiring layer 2501 coupled to the frontside via; where the backside via and the frontside contact are coupled laterally at an upper portion of the backside via (as seen at the top of the backside via 1403 in FIG. 39B).

In some instances, the backside contact, the backside via, the frontside contact conductive fill, and the frontside via are all a same conductive material. For example, the same material can be selected from the group consisting of aluminum, ruthenium, tungsten, cobalt, and copper. In one specific example, the same material is tungsten.

In one or more embodiments, the backside via has sides, and the structure further includes a backside via liner (e.g., SiN liner 1301) on the sides of the backside via. The backside via liner can include, for example, silicon nitride. Again, any of the embodiments can further include a power supply 9999 and/or a signal source 9997 as discussed above.

In another aspect, referring, for example, to FIGS. 18-19B, an exemplary method of forming a semiconductor device includes providing an initial semiconductor structure. This initial structure includes a field effect transistor including a first drain-source region (e.g., 1017 under a region 1005), a second drain-source region (e.g., 1017 under another region 1005), at least one channel region 1023 connecting the first drain-source region and the second drain-source region, and a gate 1001 at least partially contacting the at least one channel region. A backside via 1403 runs vertically upward next to the field effect transistor. A frontside contact portion including a frontside contact conductive fill (e.g., of source-drain contact 1004) and a frontside contact liner (e.g., 1703, 1705). The frontside contact liner separates the frontside contact conductive fill from one of the first drain-source region and the second drain-source region and from the backside via.

Referring, for example, to FIGS. 20A and 20B, a further step includes partially recessing the frontside contact portion to create a cavity.

Referring, for example, to FIGS. 21A and 21B, a still further step includes filling the cavity with additional conductive fill (e.g., additional tungsten 2001) that directly (i.e., no intervening material) contacts the frontside contact conductive fill and the backside via.

Referring, for example, to the additional steps discussed above, further steps include forming a back-end-of-line layer 2501 in contact with the additional conductive fill; and forming a backside power delivery network 3001 in contact with the backside via.

Those skilled in the art will appreciate that the exemplary structures discussed above can be distributed in raw form (i.e., a single wafer having multiple unpackaged chips), as bare dies, in packaged form, or incorporated as parts of intermediate products or end products that benefit from use of one or more aspects of the disclosed backside power delivery network with reduced resistance connection.

An integrated circuit in accordance with aspects of the present inventions can be employed in essentially any application and/or electronic system where one or more aspects of the disclosed backside power delivery network with reduced resistance connection would be beneficial. Given the teachings of the present disclosure provided herein, one of ordinary skill in the art will be able to contemplate other implementations and applications of embodiments disclosed herein.

The illustrations of embodiments described herein are intended to provide a general understanding of the various embodiments, and they are not intended to serve as a complete description of all the elements and features of apparatus and systems that might make use of the circuits and techniques described herein. Many other embodiments will become apparent to those skilled in the art given the teachings herein; other embodiments are utilized and derived therefrom, such that structural and logical substitutions and changes can be made without departing from the scope of this disclosure. It should also be noted that, in some alternative implementations, some of the steps of the exemplary methods may occur out of the order noted in the figures. For example, two steps shown in succession may, in fact, be executed substantially concurrently, or certain steps may sometimes be executed in the reverse order, depending upon the functionality involved. The drawings are also merely representational and are not drawn to scale. Accordingly, the specification and drawings are to be regarded in an illustrative rather than a restrictive sense.

Embodiments are referred to herein, individually and/or collectively, by the term “embodiment” merely for convenience and without intending to limit the scope of this application to any single embodiment or inventive concept if more than one is, in fact, shown. Thus, although specific embodiments have been illustrated and described herein, it should be understood that an arrangement achieving the same purpose can be substituted for the specific embodiment(s) shown; that is, this disclosure is intended to cover any and all adaptations or variations of various embodiments. Combinations of the above embodiments, and other embodiments not specifically described herein, will become apparent to those of skill in the art given the teachings herein.

The terminology used herein is for the purpose of describing particular embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. Terms such as “bottom”, “top”, “above”, “over”, “under” and “below” are used to indicate relative positioning of elements or structures to each other as opposed to relative elevation. If a layer of a structure is described herein as “over” another layer, it will be understood that there may or may not be intermediate elements or layers between the two specified layers. If a layer is described as “directly on” another layer, direct contact of the two layers is indicated. As the term is used herein and in the appended claims, “about” means within plus or minus ten percent.

The corresponding structures, materials, acts, and equivalents of any means or step-plus-function elements in the claims below are intended to include any structure, material, or act for performing the function in combination with other claimed elements as specifically claimed. The description of the various embodiments has been presented for purposes of illustration and description, but is not intended to be exhaustive or limited to the forms disclosed. Many modifications and variations will be apparent to those of ordinary skill in the art without departing from the scope and spirit thereof. The embodiments were chosen and described in order to best explain principles and practical applications, and to enable others of ordinary skill in the art to understand the various embodiments with various modifications as are suited to the particular use contemplated.

The abstract is provided to comply with 37 C.F.R. § 1.76(b), which requires an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the appended claims reflect, the claimed subject matter may lie in less than all features of a single embodiment. Thus, the following claims are hereby incorporated into the Detailed Description, with each claim standing on its own as separately claimed subject matter.

Given the teachings provided herein, one of ordinary skill in the art will be able to contemplate other implementations and applications of the techniques and disclosed embodiments. Although illustrative embodiments have been described herein with reference to the accompanying drawings, it is to be understood that illustrative embodiments are not limited to those precise embodiments, and that various other changes and modifications are made therein by one skilled in the art without departing from the scope of the appended claims.

What is claimed is:

1. A semiconductor structure comprising:
a field effect transistor including a first drain-source region, a second drain-source region, at least one channel region connecting the first drain-source region and the second drain-source region, and a gate at least partially contacting the at least one channel region;
a backside power delivery network below the field effect transistor;
a backside contact connected to the backside power delivery network;
a backside via coupled directly to the backside contact and running vertically upward next to the field effect transistor; and
a frontside contact including a frontside contact conductive fill coupled directly to the backside via and a frontside contact liner between the frontside contact conductive fill and one of the first drain-source region and the second drain-source region.

2. The semiconductor structure of claim 1, further comprising:
a substrate under the field effect transistor and laterally spaced from the backside contact;
a frontside via coupled directly to the frontside contact conductive fill; and
a back-end-of-line wiring layer coupled to the frontside via;
wherein the backside via and the frontside contact are coupled laterally at an upper portion of the backside via.

3. The semiconductor structure of claim 2, wherein the backside contact, the backside via, the frontside contact conductive fill, and the frontside via are all a same conductive material.

4. The semiconductor structure of claim 3, wherein the same conductive material is selected from the group consisting of aluminum, ruthenium, tungsten, cobalt, and copper.

5. The semiconductor structure of claim 4, wherein the same conductive material is tungsten.

6. The semiconductor structure of claim 3, wherein the backside via has sides, further comprising a backside via liner on the sides of the backside via.

7. The semiconductor structure of claim 6, wherein the backside via liner comprises silicon nitride.

8. The semiconductor structure of claim 6, wherein the frontside contact liner includes:
an inner layer adjacent the one of the first drain-source region and the second drain-source region; and
an adhesion liner between the inner layer and the frontside contact conductive fill.

9. The semiconductor structure of claim 8, wherein:
the inner layer is selected from the group consisting of nickel, nickel-platinum, and titanium; and
the adhesion liner is selected from the group consisting of titanium nitride and tantalum nitride.

10. The semiconductor structure of claim 9, wherein:
the inner layer is titanium; and
the adhesion liner is titanium nitride.

11. The semiconductor structure of claim 6, wherein the frontside contact liner is a single layer selected from the group consisting of nickel, nickel-platinum, and titanium.

12. The semiconductor structure of claim 11, wherein the single layer is titanium, further comprising a power supply coupled to the backside contact and a signal source coupled to the gate through the back-end-of-line wiring layer.

13. A semiconductor structure comprising:
a field effect transistor including a first drain-source region, a second drain-source region, at least one channel region connecting the first drain-source region and the second drain-source region, and a gate at least partially contacting the at least one channel region;
a backside power delivery network below the field effect transistor;
a backside contact connected to the backside power delivery network;
a backside via coupled directly to the backside contact and running vertically upward next to the field effect transistor; and
a frontside contact including a frontside contact conductive fill and a frontside contact liner, wherein the frontside contact liner is directly between:
the frontside contact conductive fill and one of the first drain-source region and the second drain-source region; and
the frontside contact conductive fill and the backside via.

14. The semiconductor structure of claim 13, further comprising:
a substrate under the field effect transistor and laterally spaced from the backside contact;
a frontside via coupled directly to the frontside contact conductive fill; and
a back-end-of-line wiring layer coupled to the frontside via;
wherein the backside via and the frontside contact are coupled laterally at an upper portion of the backside via.

15. The semiconductor structure of claim 14, wherein the backside contact, the backside via, the frontside contact conductive fill, and the frontside via are all a same conductive material.

16. The semiconductor structure of claim 15, wherein the same material is selected from the group consisting of aluminum, ruthenium, tungsten, cobalt, and copper.

17. The semiconductor structure of claim 16, wherein the same material is tungsten.

18. The semiconductor structure of claim 15, wherein the backside via has sides, further comprising a backside via liner on the sides of the backside via.

19. The semiconductor structure of claim 18, wherein the backside via liner comprises silicon nitride, further comprising a power supply coupled to the backside contact and a signal source coupled to the gate through the back-end-of-line wiring layer.

20. A method of forming a semiconductor device, comprising:
providing an initial semiconductor structure comprising:
a field effect transistor including a first drain-source region, a second drain-source region, at least one channel region connecting the first drain-source region and the second drain-source region, and a gate at least partially contacting the at least one channel region;
a backside via running vertically upward next to the field effect transistor; and
a frontside contact portion including a frontside contact conductive fill and a frontside contact liner, the frontside contact liner separating the frontside contact conductive fill from one of the first drain-source region and the second drain-source region and from the backside via;
partially recessing the frontside contact portion to create a cavity;
filling the cavity with additional conductive fill that directly contacts the frontside contact conductive fill and the backside via;
forming a back-end-of-line layer in contact with the additional conductive fill; and
forming a backside power delivery network in contact with the backside via.
